(19) United States
(12) Patent Application Publication
(10) Pub. No.: US 2007/0046305 A1
(43) Pub. Date: Mar. 1, 2007

(54) Wafer holder and wafer prober having the same

(76) Inventors: Tomoyuki Awazu, Itami-shi (JP); Katsuhiro Itakura, Itami-shi (JP); Masuhiro Natsuhara, Itami-shi (JP); Hirohiko Nakata, Itami-shi (JP)

Correspondence Address: MCDERMOTT WILL & EMERY LLP, 600 13TH STREET, N.W., WASHINGTON, DC, 20005-3096, US

(21) Appl. No.: 11/498,255

(22) Filed: Aug. 3, 2006

(30) Foreign Application Priority Data
Aug. 4, 2005 (JP) 2005-226204 (P)

(51) Int. Cl. G01R 31/02

(52) U.S. Cl. 324/760; 324/754

(57) ABSTRACT

A wafer holder that can improve throughput by improving heating rate and thermal uniformity of a prober, as well as a wafer prober having the same are provided. The wafer holder has a chuck top conductive layer on a surface of a chuck top, and a heater body at a portion other than the portion where the chuck top conductive layer is formed, wherein maximum outer diameter l of an area where the heater body exists is smaller than diameter L of the chuck top, and the maximum outer diameter l and thickness t of the chuck top are set such that the thickness t and diameter Wl of a wafer to be inspected satisfy the relation of 1+4t>Wl.

### BACKGROUND OF THE INVENTION

1. Field of the Invention

The present invention relates to a wafer holder suitably used for a wafer prober in which a semiconductor wafer is mounted on a wafer-mounting surface and a probe card is pressed onto the wafer for inspecting electric characteristics of the wafer, as well as to a wafer prober having the same.

2. Description of the Background Art

Conventionally, in the step of inspecting a semiconductor wafer, a semiconductor substrate (wafer) as an object of processing is subjected to heat treatment. Specifically, burn-in is performed in which the wafer is heated to a temperature higher than the temperature of normal use, to accelerate degradation of a possibly defective semiconductor chip and to remove the defective chip, in order to prevent defects after shipment. In the burn-in process, after semiconductor circuits are formed on the semiconductor wafer and before cutting the. wafer into individual chips, electrical characteristics of each chip are measured and defective ones are removed while the wafer is heated. In the burn-in process, reduction of process time is strongly desired in order to improve throughput.

In this process, a large number of semiconductor chips on the semiconductor wafer are inspected. The large number of chips on the wafer must be inspected under same conditions, and therefore, it is necessary that the temperature of the wafer be increased uniformly when the wafer is heated. Therefore, a heater for heating the wafer must have high thermal uniformity and small range of temperature distribution.

In the burn-in process as such, a chuck top having a heater for heating the wafer contained therein is used. Conventionally, chuck tops formed of metal have been used, as it is necessary to have the entire rear surface of the wafer in contact with the ground electrode. At the time of measurement, a wafer having circuits formed thereon is placed on the chuck top formed of metal and having the heater therein, and electric characteristics of the chips are measured. The wafer holder mounting the chuck top is moved by a driving system to a prescribed position, and the wafer is pressed to a prober referred to as a probe card, having a number of electrode pins for electric conduction, with a force of several tens to several hundreds kgf, and such operations are repeated. Therefore, when the chuck top is thin, the chuck top might possibly be deformed, resulting in contact failure between the wafer and a probe pin. Therefore, it is necessary to use a thick metal plate having the thickness of at least 15 mm, for maintaining rigidity of the chuck top and the wafer holder. As a result, it takes long time to increase and decrease temperature of the heater, which is a significant drawback in improving the throughput.

In view of the foregoing, Japanese Patent Laying-Open No. 2001-033484 proposes a wafer prober having a ceramic substrate that is thin but has high rigidity and is not susceptible to deformation with a thin metal layer formed on its surface, in place of a thick metal plate, to be less susceptible to deformation and to have smaller thermal capacity. According to this reference, the chuck top has high rigidity and therefore it does not cause contact failure, and as it has small thermal capacity, it allows heating and cooling in a short period of time. It is described that as a support base for mounting the wafer prober, an aluminum alloy or stainless steel may be used.

As described in Japanese Patent Laying-Open No. 2001-033484, however, when the wafer prober is supported only by the outermost circumference, the wafer prober may warp when pressed by the probe card, and therefore, it has been necessary to devise measures, such as providing a number of pillars.

Further, recently, as the semiconductor processes have come to be miniaturized, the load applied per unit area at the time of measurement has been increased, and therefore, only by the technique described above, deformation at the time of measurement cannot sufficiently be suppressed, and contact failure cannot fully be prevented. At the same time, as the semiconductor processes have come to be miniaturized, high accuracy of registration between the probe card and the wafer holder comes to be required. There is a problem that when the wafer is heated to a prescribed temperature, that is, to about 100 to 200° C., the heat is transferred to the driving system for moving the wafer holder, and metal components forming the driving system thermally expand, degrading positional accuracy.

Further, along with the increase in load at the time of probing, rigidity of the prober itself mounting the wafer has come to be required. Specifically, when the prober itself deforms because of the load at the time of probing, uniform contact of the pins of probe card with the wafer would fail and inspection becomes impossible, or in the worst case, the wafer would be broken. In order to suppress deformation of the prober, the prober has been made larger and its weight has been increased, posing a problem that the increased weight adversely influences the accuracy of the driving system. Further, as the prober is made larger, the time for heating and cooling the prober becomes extremely long, posing another problem of lower throughput.

Further, in order to improve throughput, it is often the case that a cooling mechanism is provided for improving the heating/cooling rate of the prober. Conventionally, however, the cooling mechanism has been air-cooling as described in Japanese Patent Laying-Open No. 2001-033484, or a cooling plate has been provided immediately below the heater formed of metal. The former approach has a problem that cooling rate is slow, as it is air-cooling. The latter approach also has a problem that, as the cooling plate is metal and the pressure of the probe card directly acts on the cooling plate at the time of probing, it is susceptible to deformation.

### SUMMARY OF THE INVENTION

The present invention was made to solve the above-described problems. Specifically, an object of the present invention is to provide a wafer holder that can improve through put by improving heating rate and thermal uniformity of the prober in the process of mounting a semiconductor wafer on a wafer-mounting surface and pressing the probe card to the wafer for inspecting electric characteristics of the wafer, as well as to provide a wafer prober including the same.

The present invention relates to a wafer holder, including a chuck top, a chuck top conductive layer formed on a surface of the chuck top, and a heater body formed on a portion other than the portion where the chuck top conductive layer is formed, of the chuck top, wherein maximum outer diameter l of an area where the heater body exists is smaller than diameter L of the chuck top, and the maximum outer diameter l of the area where the heater body exists and thickness t of the chuck top are set such that the maximum outer diameter l, the thickness t and diameter Wl of a wafer to be inspected satisfy the relation of 1+4t>Wl.

Preferably, a cooling module is further provided on a side opposite to the wafer-mounting surface of the chuck top, and the diameter of the cooling module is smaller than the diameter of the chuck top, and preferably, it is larger than the diameter of the heater body. Preferably, the cooling module is fixed on the chuck top.

Preferably, the heater body is provided between the chuck top and the cooling module, and it may be provided on a surface opposite to the wafer-mounting surface of the chuck top.

The present invention also relates to a wafer prober including the wafer holder described above. The wafer prober has high rigidity and attains high heat-insulating effect, and therefore, by the wafer prober, it is possible to improve positional accuracy and thermal uniformity and to realize rapid heating and cooling of the chip.

The present invention provides a wafer holder that can reduce process time, which is required to improve throughput, by improving heating rate and thermal uniformity of the prober in the process of mounting a semiconductor wafer on a wafer-mounting surface and pressing the probe card to the wafer for inspecting electric characteristics of the wafer.

The present invention also provides a wafer prober including the wafer holder described above.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view showing an exemplary cross-sectional structure of a wafer holder in accordance with the present invention.

FIG. 2 is a cross-sectional view showing an exemplary cross-sectional structure of the heater body in accordance with the present invention.

FIGS. 3 to 5 are plan views showing examples of the heat-insulating structure in accordance with the present invention.

FIG. 6 is a cross-sectional view showing an exemplary cross-sectional structure of a wafer holder in accordance with the present invention.

FIG. 7 is a cross-sectional view showing an exemplary cross-sectional structure of an electrode portion of the wafer holder in accordance with the present invention.

FIGS. 8 to 10 are cross-sectional views showing exemplary cross-sectional structures of the wafer holder in accordance with the present invention.

### DESCRIPTION OF THE PREFERRED EMBODIMENTS

In a chuck top having a conductive layer on a wafer-mounting surface and having a suction trench for vacuum chucking a wafer and a heater body on a lower surface, the wafer-mounting surface of the chuck top is heated by heat transfer from the heater body provided on the lower surface of the chuck top through the chuck top. Therefore, in order to increase heating rate of the wafer-mounting surface through improved response, it is desirable to make the chuck top thin.

On the other hand, heating by the heater unit is local, and therefore, in order to attain highly uniform temperature distribution at the wafer-mounting surface as the upper surface of the chuck top from the temperature distribution generated by the local heating at the lower surface of the chuck top, it is necessary to relax the local temperature distribution. For this purpose, a thick chuck top is desirable. Specifically, there is a trade-off between the thermal uniformity and the heating rate necessary to reduce process time, as regards the shape of chuck top.

Typically, when there is such a trade-off, a factor as the object of trade-off (here, thickness of the chuck top) is varied and a point where two required results (here, heating rate and thermal uniformity) are both as good as possible is found, that is, optimization is done, and the factor is designed by the thus determined value. The present invention successfully found, other than the thickness of chuck top as the object factor of the conventional method, a factor that can improve the heating rate and the thermal uniformity. Specifically, focusing on a factor other than the chuck top thickness, it is found that, in a wafer holder including the chuck top, the chuck top conductive layer and the heater body, the heating rate can be increased while superior thermal uniformity is maintained, by designing the heater body and the chuck top such that maximum outer diameter l of an area where the heater exists (typically, the maximum outer diameter of the heater body) is made smaller than the diameter L of the chuck top, and that the maximum outer diameter l of an area where the heater exists, the chuck top thickness t and the diameter Wl of the wafer to be inspected satisfy the relation of 1+4t>Wl. Preferably, the chuck top has a suction trench on its surface, for vacuum chucking the wafer.

Further, it is found that, in a chuck top having a cooling module on the side opposite to the wafer-mounting surface and satisfying the relation above, the heating rate and the thermal uniformity can be improved while cooling rate is increased, by making the diameter of the cooling module smaller than the diameter of the chuck top.

An embodiment of the present invention will be described with reference to FIG. 1. In the figures of the present invention, members or portions denoted by the same reference characters denote the members or portions having similar functions unless otherwise specified. A wafer holder 100 in accordance with the present invention has a chuck top 2 having a chuck top conductive layer 3, and a supporter 4 supporting chuck top 2. Further, supporter 4 may be mounted on a driving system (not shown) for moving the wafer holder as a whole.

Preferably, there is a space 5 between chuck top 2 and a part of supporter 4. Better heat-insulating effect can be attained by providing space 5. The shape of space 5 is not specifically limited, and it may have any shape that can suppress as much as possible the amount of transfer of cool air or heat generated at chuck top 2 to supporter 4. It is preferred that supporter 4 has a hollow cylindrical shape with a bottom, as the contact area between chuck top 2 and supporter 4 can be reduced and space 5 can readily be formed. When such a space 5 is formed, what lies between chuck top 2 and supporter 4 is mostly an air layer, and hence, an efficient heat insulating structure can be formed.

Preferably, chuck top 2 includes a heater body 6. In the step of inspecting a semiconductor, heating of a wafer may or may not be required. Recently, however, it is more often the case that heating to 100 to 200° C. is required. In the present invention, the heater body is preferably provided on a surface opposite to the wafer-mounting surface of the chuck top. In this case, the chuck top can be heated and maintained at the high temperature with high efficiency.

In the wafer holder, if the transfer of heat of the heater body heating the chuck top to the supporter cannot be prevented, the heat would be transferred to the driving system provided below the supporter of wafer prober, and because of difference in thermal expansion coefficient among components, machine accuracy would be deviated, possibly causing significant deterioration in flatness and parallelism of the upper surface (wafer-mounting surface) of the chuck top. When the wafer holder has the heat-insulating structure, the flatness and parallelism would not. significantly be degraded. Further, when supporter 4 has a hollow structure with space 5, the weight can be reduced as compared with a supporter having a solid cylindrical shape.

The inventors have found a method that can improve the heating rate for higher throughput and improve thermal uniformity. Specifically, the thickness of chuck top 2 having the wafer-mounting surface should desirably be thin, in order to quickly transfer the heat from the heater body at the lower surface and to increase heating rate. On the other hand, the thickness of chuck top 2 should desirably be thick to improve thermal uniformity, as the temperature distribution at the heater body portion is relaxed while the heat is transferred. The inventors have found a method of solving the trade-off problem of chuck top thickness, by focusing on the relation between the chuck top diameter and the wafer diameter.

Specifically, it has been found that when the maximum outer diameter 1 of the area where heater body 6 exists is made smaller than the diameter L of chuck top 2 and the maximum outer diameter l, thickness t of chuck top 2 and the diameter Wl of the wafer to be inspected satisfy the relation of 1+4t>Wl, heating rate can be increased while superior thermal uniformity (temperature distribution in the wafer) is maintained. When the maximum outer diameter of heater body 6 is made larger than the diameter of chuck top 2, it follows that the heater body 6 protrudes from chuck top 2, and the heat generated from heater body 6 as such would not be well utilized as heat for heating, possibly deteriorating thermal uniformity (temperature distribution) of chuck top 2. When the relation described above is not satisfied with respect to the diameter Wl of the wafer to be inspected, the area of heater body 6 relative to the wafer would be too small, and the heat source necessary for temperature increase would be too local, so that sufficient heating rate would not be attained, and in addition, thermal uniformity would also be deteriorated, as uniform heating is impossible.

In the present invention, in the process of mounting a semiconductor wafer on a wafer-mounting surface and pressing the probe card to the wafer for inspecting electric characteristics of the wafer, thermal uniformity and heating rate necessary for the reduction of process time, which is required for improving throughput, can be improved.

The diameter Wl of the wafer to be inspected by the wafer holder in accordance with the present invention is typically at least 8 inches, and more typically, in the range of 8 to 12 inches.

The present invention also provides a method of inspecting a wafer using a wafer holder including a chuck top, a chuck top conductive layer formed on a surface of the chuck top, and a heater body formed at a portion other than the portion where the chuck top conductive layer is formed, of the chuck top. In the method of inspection, a combination of the wafer holder and the wafer is selected such that the maximum outer diameter l of the area where the heater body exists is made smaller than the diameter L of chuck top 2 and the maximum outer diameter l, thickness t of the chuck top and the diameter Wl of the wafer to be inspected satisfy the relation of 1+4t>Wl, and with this combination, the wafer is inspected.

In the method of inspection, particularly when the wafer holder additionally having a cooling module is used, it is preferred that the diameter of the cooling module is made smaller than the diameter of the chuck top. Further, it is also preferred that the diameter of the cooling module is made smaller than the diameter of the heater body.

In the present invention, the following contents may also be implemented.

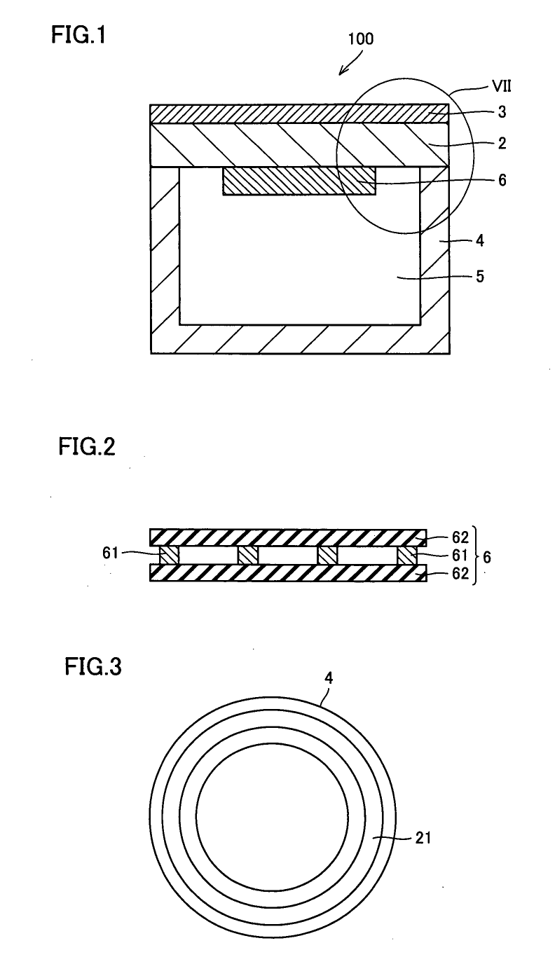

As shown in FIG. 2, as heater body 6, one having a resistance heater body 61 sandwiched by an insulator 62 such as mica is preferred, as the structure is simple. As the material of resistance heater body 61, metal material may be used. By way of example, metal foil of nickel, stainless steel, silver, tungsten, molybdenum, chromium and an alloy of these may be used. Of these metals, stainless steel or nichrome is preferred. Stainless steel or nichrome allows formation of a circuit pattern of resistance heater body with relatively high precision by a method such as etching, when it is processed to the shape of the heater body. Further, it is preferred because it is inexpensive, and is oxidation resistant and withstands use for a long period of time even when the temperature of use is high. Insulator 62 sandwiching resistance heater body 61 is not specifically limited, and a heat-resistant insulator is preferred. By way of example, mica, silicone resin, epoxy resin, phenol resin or the like may be used. When insulator 62 is resin, filler may be dispersed in the resin, in order to improve thermal conductivity of insulator 62. Filler material is not specifically limited, provided that it does not have reactivity to the resin, and a substance such as boron nitride, aluminum nitride, alumina, silica or the like may be available. Heater body 6 may be fixed on chuck top 2 by, for example, a mechanical method such as screw fixing.

As to the method of forming heater body 6, heater body 6 may be formed by the method of forming an insulating layer through a method of thermal spraying or screen printing on a surface opposite to the wafer-mounting surface and then by forming the conductive layer in a prescribed shape through a method such as screen printing or vapor deposition, other than the method described above.

When chuck top 2 is heated by heater body 6 and inspection is done, for example, at 200° C., it is preferred that the temperature at the bottom surface of supporter 4 is at most 100° C. When the temperature exceeds 100° C., contact failure possibly occurs because of thermal expansion of the wafer holder. When inspection is to be done at a room temperature after inspecting the wafer at 200° C., cooling takes long time and hence, throughput would be decreased.

It is preferred that supporter 4 has Young's modulus of at least 200 GPa. In this case, deformation of supporter 4 itself can be made small, and hence, deformation of chuck top 2 can further be suppressed. More preferable Young's modulus of supporter 4 is at least 300 GPa. Young's modulus of supporter 4 of 300 GPa or higher is particularly preferred, as deformation of supporter 4 can significantly be reduced and hence supporter 4 can further be reduced in size and weight.

Supporter 4 preferably has thermal conductivity of at most 40 W/mK. Then, the amount of heat transferred from chuck top 2 through supporter 4 to the driving system of the wafer holder is further reduced, and temperature increase of the driving system can effectively be prevented. Recently, a temperature as high as 150° C. is required at the time of probing, and therefore, it is more preferred that supporter 4 has thermal conductivity of at most 10 W/mK. More preferable thermal conductivity is at most 5 W/mK. With the thermal conductivity of this range, the amount of heat transfer from supporter 4 to the driving system decreases significantly.

In the present invention, Young's modulus may be measured, for example, by the pulse method or the flexural resonance method. The thermal conductivity may be measured by a method such as laser flash method, using pelletized samples.

As a material having good flatness, allowing processing to the shape as described above and having Young's modulus and thermal conductivity as described above as physical properties, mullite, alumina or a composite material of mullite and alumina is preferred, considering processability and cost. Mullite is preferred as it has low thermal conductivity and attains high heat insulating effect, and alumina is preferred as it has high Young's modulus and high rigidity. Mullite-alumina composite is generally preferred as the thermal conductivity is lower than alumina and Young's modulus is higher than mullite.

When supporter 4 has a hollow cylindrical shape with a bottom, it is preferred that the radial thickness of the hollow cylindrical portion of supporter 4 is at most 20 mm. When the radial thickness exceeds 20 mm, the amount of heat transferred from chuck top 2 through supporter 4 to the driving system of wafer holder may possibly increase. When the radial thickness is smaller than 1 mm, supporter 4 itself tends to be deformed or damaged by the load of the probe card. The most preferable radial thickness is 10 to 15 mm. Further, that portion of the hollow cylindrical portion which is in contact with chuck top 2 should preferably have the radial thickness of 2 to 5 mm, as good balance between the strength and heat insulating characteristic of supporter 4 can be attained.

Further, it is preferred that the height of hollow cylindrical portion of supporter 4 is at least 10 mm. When the height is lower than 10 mm, the pressure from probe card acts on chuck top 2 at the time of wafer inspection, and the pressure further propagates to supporter 4. As a result, the base portion of supporter 4 would deflect, possibly degrading flatness of chuck top 2.

The base portion of supporter 4 preferably has the thickness of at least 10 mm. When the thickness of the base portion of supporter 4 is smaller than 10 mm, supporter 4 itself may possibly be deformed or damaged by the load of the probe card. More preferable thickness of the base portion of supporter 4 is 10 mm to 35 mm. When the thickness is smaller than 10 mm, the heat of chuck top 2 is easily transferred to the base portion of supporter 4, and supporter may warp because of thermal expansion, possibly degrading flatness and parallelism of chuck top 2. The thickness of at most 35 mm is preferred, as supporter 4 can be reduced in size. Further, it is also possible to form the hollow cylindrical portion and the base portion of supporter 4 separable from each other. In that case, as the separated hollow cylindrical portion and the base portion have interface to each other and the interface serves as a thermal resistance layer, so that the heat transferred from chuck top 2 to supporter 4 is once intercepted by the interface, and the temperature increase of the base portion is suppressed.

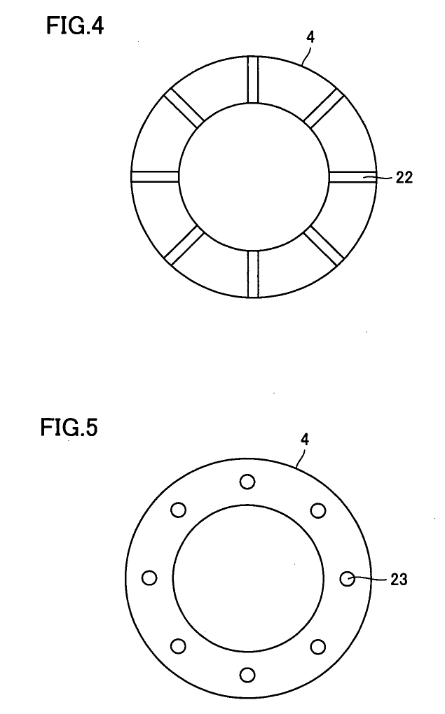

It is preferred that the support surface of supporter 4 supporting chuck top 2 has a heat insulating structure. The heat insulating structure may be formed by forming a notch in supporter 4, thereby reducing the contact area between chuck top 2 and supporter 4. It is also possible to form the heat insulating structure by forming a notch in chuck top 2. In that case, it is preferred that chuck top 2 has Young's modulus of at least 250 GPa. As the pressure from the probe card acts on chuck top 2, the amount of deformation of chuck top 2 would inevitably increase if a notch exists and Young's modulus of the material is small, and when the amount of deformation increases, damage to the wafer or damage to chuck top 2 itself may possibly result. Formation of the notch in supporter 4 is preferred, because such a problem can be avoided. As to the shape of the notch, by way of example, concentric circular trench 21 such as shown in FIG. 3, or a plurality of radial trenches 22 arranged radially as shown in FIG. 4, or a number of projections may be formed, and the shape is not specifically limited. It is necessary, however, that the shape is in axial symmetry. If the shape is axially asymmetrical, it becomes impossible to uniformly disperse the pressure applied to chuck top 2, possibly resulting in deformation or damage to chuck top 2.

As a form of the heat insulating structure, it is preferred to provide a plurality of pillars 23 between chuck top 2 and supporter 4, as shown in FIG. 5. It is preferred that at least 8 pillars 23 are in uniform, concentric arrangement or in a similar arrangement. Recently, wafer size has come to be increased to 8 to 12 inches, and therefore, if the number is smaller than 8, distance between pillars 23 to each other would be long, and when the pins of the probe card are pressed to the wafer mounted on chuck top 2, deflection would be more likely between the pillars 23. When pillars 23 are formed, assuming that the contact area with chuck top 2 is the same as in the integral type supporter 4, two interfaces can be formed between chuck top 2 and pillar 23 and between pillar 23 and supporter 4, and as the interfaces serve as thermal resistance layers, the number of thermal resistance layers can be increased twice as much, whereby the heat generated in chuck top 2 can effectively be insulated. The shape of pillars 23 is not specifically limited, and it may be a cylinder or it may be a triangular pole, a quadrangular pole or a polygonal pole with any polygon as a bottom surface. In any case, by inserting pillars 23 in this manner, the heat from chuck top 2 to supporter 4 can effectively be intercepted.

As a material for pillars 23 used in the heat insulating structure described above, one having thermal conductivity of at most 30 W/mK is preferred. When the thermal conductivity is higher, the heat insulating effect tends to decrease. As the material of pillars 23, Si₃N₄, mullite, mullite-alumina composite, steatite, or cordierite, stainless steel, glass (fiber), or heat resistant resin such as polyimide, epoxy or phenol may be used, or a composite thereof may be used.

It is preferred that the surface roughness Ra at the contact portion between supporter 4 and chuck top 2 or pillar 23 is at least 0.1 μm. When the surface roughness Ra is at least 0.1 μm, thermal resistance at the contact surface between supporter 4 and chuck top 2 increases, and the amount of heat transferred to the driving system of the wafer holder can be reduced. Though the upper limit of surface roughness Ra is not specifically limited, when the surface roughness Ra exceeds 5 μm, the cost for surface processing tends to increase. As for the method of realizing surface roughness Ra of at least 0.1 μm, polishing process or sand blasting may be used.

In the present invention, surface roughness Ra represents arithmetic mean deviation, of which detailed definition can be found, for example, in JIS B 0601.

In addition to the contact surface between supporter 4 and chuck top 2, the surface roughness Ra at the contact surface between the bottom surface of supporter 4 and the driving system, the contact surface between the base portion of supporter 4 and the hollow cylindrical portion when the base portion and the hollow cylindrical portion are made separable, at the contact surface between the base portion or the hollow cylindrical portion of supporter 4 and pillar 23 when pillars 23 are separable, and at the contact surface between the hollow cylindrical portion and the plurality of pillars 23 when the hollow cylindrical portion and the plurality of pillars 23 are used in combination, should also be at least 0.1 μm as in the foregoing, because the thermal resistance is increased and the amount of heat transferred to the driving system of the wafer holder can be reduced. Reduction in heat quantity transferred to the driving system, attained by the increased thermal resistance, leads to reduction of power supply to the heating body.

Perpendicularity at a contact surface between an outer circumferential portion of the hollow cylindrical portion of supporter 4 and chuck top 2, or at a contact surface between an outer circumferential portion of the hollow cylindrical portion of supporter 4 and pillar 23 should preferably be at most 10 mm, with the measured length converted to 100 mm. When perpendicularity is larger than that and the pressure applied from chuck top 2 acts on the hollow cylindrical portion of supporter 4, the hollow cylindrical portion itself may possibly deform more easily.

It is preferred that a metal layer is formed on the surface of supporter 4. Electric field or electromagnetic wave generated by heater body 6 for heating chuck top 2, a prober driving unit or by peripheral apparatuses may affect wafer inspection as noise. Formation of the metal layer on supporter 4 is preferred, as it can intercept (shield) the electromagnetic wave. The method of forming the metal layer is not specifically limited. By way of example, a conductive paste prepared by adding glass frit to metal powder of silver, gold, nickel or copper may be applied using a brush and burned.

Alternatively, metal such as aluminum or nickel may be thermally sprayed to form the metal layer. The metal layer may be formed by plating on the surface. Further, combination of these methods is also possible. Specifically, metal such as nickel or the like may be plated after burning the conductive paste, or plating may be done after thermal spraying. Among these methods, plating is preferred, as it has high contact strength and is highly reliable. Further, thermal spraying is preferred as it allows formation of the metal film at a relatively low cost.

As another method, a conductor having a circular tube shape may be attached on a side surface of supporter 4. The material used here is not specifically limited, as long as it is a conductor. By way of example, metal foil or a metal plate of stainless steel, nickel, aluminum or the like may be formed to have a circular tube shape of a size larger than the outer diameter of supporter 4, and it may be attached on the side surface of supporter 4. Further, at the bottom surface portion of supporter 4, metal foil or a metal plate may be attached, and by connecting this to the metal foil or metal plate attached to the side surface of supporter 4, the effect of shielding the electromagnetic wave can be enhanced. Further, utilizing the space 5 inside supporter 4, the metal foil or metal plate may be attached inside the space, and by connecting this to the metal foil or metal plate attached to the side surface and the bottom surface, the effect of shielding the electromagnetic wave can be enhanced. Adopting such method is preferred, because the electromagnetic wave can be shielded at a lower cost than when plating is done or a conductive paste is applied. Though the method of fixing the metal foil or the metal plate to supporter 4 is not specifically limited, the metal foil or metal plate may be attached to supporter 4 using, for example, metal screws. Further, the metal foil or the metal plates on the bottom surface and on the side surface may be integrated beforehand and then fixed on supporter 4.

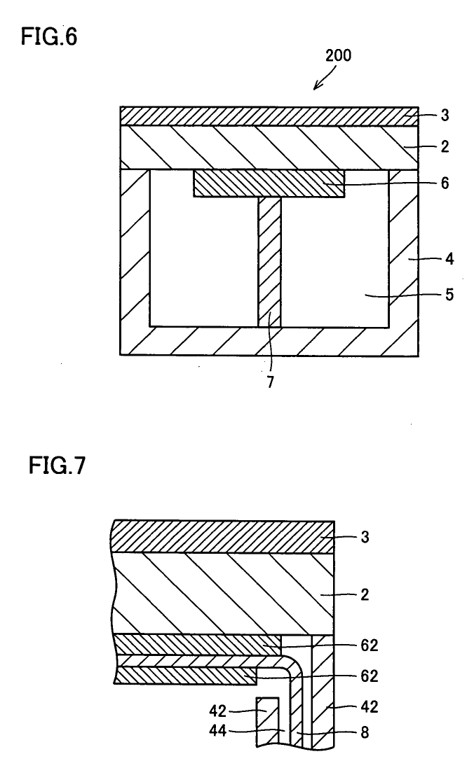

Further, as shown in wafer holder 200 of FIG. 6, it is preferred that a support rod 7 is provided near the central portion of supporter 4. Support rod 7 can further suppress deformation of chuck top 2 when load is applied by the probe card. It is preferred that the material of support rod 7 is the same as that of the hollow cylindrical portion of supporter 4 or of the pillars. When the hollow cylindrical portion or pillar and support rod 7 thermally expand because of the heat from heater body 6 and the materials are different, a step would undesirably be generated between the hollow cylindrical portion or pillar and support rod 7, because of the difference in thermal expansion coefficient. As to the size of support rod 7, it is preferred that the radial cross-sectional area is at least 0.1 cm². When the cross-sectional area is smaller than 0.1 cm², satisfactory supporting effect would not be attained, and support rod 7 tends to deform. The cross-sectional area should preferably be at most 100 cm². When the cross-sectional area exceeds 100 cm², the amount of heat transferred to the driving system tends to increase. The shape of support rod 7. is not specifically limited, and it may be a cylinder, a triangular pole, a quadrangular pole, a pipe or the like. As the method of fixing support rod 7 to supporter 4, methods such as brazing with an active metal, glass fixing, or screw fixing may be used, and among these, screw fixing is particularly preferred. Screw fixing facilitates attachment/detachment, and as heat treatment is not involved at the time of fixing, deformation of supporter 4 or support rod 7 by the heat treatment can be avoided.

It is preferred that the electromagnetic shield layer for shielding the electromagnetic wave is also formed between heater body 6 heating chuck top 2 and chuck top 2. For forming the electromagnetic shield layer, the method of forming a metal layer on the surface of supporter 4 such as described above may be used, and, by way of example, metal foil may be inserted between heater body 6 and chuck top 2. The material of metal foil to be used is not specifically limited, and stainless steel, nickel or aluminum may be used.

Further, it is preferred that an insulating layer is provided between the electromagnetic shield layer and chuck top 2. The insulating layer serves to cut off noise that affects inspection of the wafer, such as the electromagnetic wave or electric field generated at heater body 6 and the like. The noise particularly has significant influence on measurement of high-frequency characteristics of the wafer, and the noise does not have much influence on the measurement of normal electric characteristics. Though most of the noise generated at the heater body 6 is shielded by the electromagnetic shield layer, in terms of electric circuit, a capacitor is formed between chuck top conductive layer 3 formed on the wafer-mounting surface of chuck top 2 and the electromagnetic shield layer when chuck top 2 is an insulator, or between chuck top 2 itself and heater body 6 when chuck top 2 is a conductor, and the capacitor may have an influence as a noise at the time of inspecting the wafer. In order to reduce the influence, the insulating layer may be formed between the electromagnetic shield layer and chuck top 2.

Further, it is preferred that a guard electrode layer is formed between chuck top 2 and the electromagnetic shield layer with an insulating layer interposed. When the guard electrode layer is connected to the metal layer formed on supporter 4, the noise that affects measurement of high-frequency characteristic of the wafer can further be reduced. Specifically, in the present invention, when supporter 4 as a whole including heater body 6 is covered by a conductor, the influence of noise at the time of measuring wafer characteristics at a high frequency can be reduced. When the guard electrode layer is connected to the metal layer provided on supporter 4, the influence of noise can further be reduced.

At this time, it is preferred that the resistance value of the insulating layer described above is at least 1×10⁷Ω. When the resistance value is smaller than 1×10⁷Ω, small current flows to chuck top conductive layer 3 because of the influence of heater body 6, which small current possibly becomes noise at the time of probing and affects probing. It is preferred that resistance value of the insulating layer is at least 1×10⁷Ω, as the small current described above can sufficiently be reduced not to affect probing. Recently, circuit patterns formed on wafers have been miniaturized, and therefore, it is preferable to reduce such noise as much as possible. When the resistance value of the insulating layer is at least 1×10¹⁰Ω, reliability can further be enhanced.

Further, it is preferred that the dielectric constant of the insulating layer is at most 10. When the dielectric constant of the insulating layer exceeds 10, charges tend to be stored more easily at the electromagnetic shield layer sandwiching the insulating layer, the guard electrode layer and chuck top 2, which might possibly be a cause of noise generation. Particularly, as the wafer circuits have been much miniaturized in these days as described above, it is preferable to reduce noise, and therefore, dielectric constant should preferably be at most 4 and more preferably at most 2. Setting small the dielectric constant is preferred, as the thickness of the insulating layer necessary for ensuring the insulation resistance value and the capacitance can be made thinner, and hence, thermal resistance posed by the insulating layer can be reduced.

Further, when chuck top 2 is an insulator, capacitance between chuck top conductive layer 3 and the guard electrode layer and between chuck top conductive layer 3 and the electromagnetic shield layer, or when chuck top 2 is a conductor, the capacitance between chuck top 2 itself and the guard electrode layer and between chuck top 2 itself and the electromagnetic shield layer, should preferably be at most 5000 pF. When the capacitance exceeds 5000 pF, the influence of the insulating layer as a capacitor would be too large, possibly causing noise and affecting probing. Capacitance of at most 1000 pF is preferred, as it enables inspection free of noise influence of even a miniaturized circuitry.

As described above, by controlling the resistance value, dielectric constant and capacitance of the insulating layer in the ranges described above, noise at the time of inspection can significantly be reduced.

The thickness of the insulating layer should preferably be at least 0.2 mm. In order to reduce the size of the device and to maintain good heat conduction from heater body 6 to chuck top 2, the thickness of the insulating layer should be small. When the thickness of the insulating layer is smaller than 0.2 mm, however, defects in the insulating layer itself or problems in durability would be generated. It is preferred that the thickness of the insulating layer is at least 1 mm, because such a thickness prevents the problem of durability and ensures good heat conduction from the heater body 6. The thickness of the insulating layer is preferably at most 10 mm. When the thickness exceeds 10 mm, though the noise cutting effect is good, the time of conduction of heat generated by heater body 6 to chuck top 2 and to the wafer becomes too long, and hence, it possibly becomes difficult to control the heating temperature. Though it depends on the conditions of inspection, the thickness of the insulating layer of at most 5 mm is particularly preferred, as temperature control is relatively easy.

The thermal conductivity of the insulating layer is preferably at least 0.5 W/mK, as it realizes good heat conduction from heater body 6 as described above. Thermal conductivity of at least 1 W/mK is preferred, as heat conduction is further improved.

As the material for the insulating layer, any material that satisfies the characteristics described above and has heat resistance sufficient to withstand the inspection temperature may be used, and ceramics or resin may be available. Filler may be dispersed in the resin. Of these, resin such as silicone resin or the silicone resin having filler dispersed therein, and ceramics such as alumina, may preferably be used. The filler dispersed in the resin serves to improve heat conduction of the resin. Any material having no reactivity to the resin may be used as the filler, and by way of example, substances such as boron nitride, aluminum nitride, alumina and silica may be available.

Further, it is preferred that the area for forming the insulating layer is the same as or larger than the area for forming the electromagnetic shield layer, the guard electrode or heater body 6. When the area for forming the insulating layer is. smaller than the area for forming the electromagnetic shield layer, the guard electrode or heater body 6, noise may possibly enter from a portion not covered with the insulating layer.

A specific example of the insulating layer will be described in the following. In the following, an example will be described in which silicone resin having boron nitride dispersed therein is used as the material for the insulating layer. The material has thermal conductivity of about 5 W/mK, and dielectric constant of 2. When the silicone resin with boron nitride dispersed is inserted as the insulating layer between the electromagnetic shield layer and chuck top 2, and the chuck top corresponds to a 12-inch wafer, it may be formed, for example, to have the diameter of 300 mm. Here, when the thickness of the insulating layer is set to 0.25 mm, capacitance of 5000 pF can be attained. When the thickness is set to 1.25 mm or more, capacitance of 1000 pF or lower can be attained. Volume resistivity of the material is 9×10¹⁵Ω·cm, and therefore, when the diameter is 300 mm and the thickness is made at least 0.8 mm, the resistance value of at least 1×10¹²Ω can be attained. Therefore, when the thickness is made at least 1.25 mm, an insulating layer having sufficiently low capacitance and sufficiently high resistance value can be obtained.

FIG. 7 shows, in enlargement, a contact portion between chuck top 2 and the hollow cylindrical portion, when supporter 4 has the hollow cylindrical potion. FIG. 7 illustrates, in enlargement, the region surrounded by a circle in FIG. 1. It is preferred that at hollow cylindrical portion 42 of supporter 4, a through-hole 44 for inserting an electrode line 8 for feeding power to heater body 62 or an electrode line of the electromagnetic shield is formed, as handling of the electrode line is facilitated. Here, the position for forming through hole 44 is preferably close to an inner circumferential surface of the hollow cylindrical portion 42, as the decrease in strength of hollow cylindrical portion 42 can be minimized. It is noted that the electrode line and the through hole are not shown in figures other than FIG. 7, for the purpose of simplicity.

It is preferred that warp of chuck top 2 is at most 30 μm. When the warp exceeds 30 μm, contact with a needle of the probe card may possibly be biased at the time of inspection, resulting in a contact failure. Similarly, if the parallelism between the surface of the chuck top conductive layer 3 and the rear surface at the bottom portion of supporter 4 exceeds 30 μm, the contact failure possibly occurs. It is preferred that warp and parallelism described above are at most 30 μm not only at the room temperature but in the temperature range of −70° C. to 200° C., in which probing is typically done.

The warp and parallelism may be measured using, for example, a three-dimensional measuring apparatus.

Chuck top conductive layer 3 formed on the wafer-mounting surface of chuck top 2 has a function of a ground electrode and, in addition, has the functions of shielding the electromagnetic noise from heater body 6 and protecting chuck top 2 from corrosive gas, acid, alkali chemical, organic solvent or water.

Possible methods of forming chuck top conductive layer 3 include a method in which a conductive paste is applied by screen printing and then fired, vapor deposition or sputtering, thermal spraying and plating. Among these, thermal spraying and plating are particularly preferred. These methods do not involve heat treatment at the time of forming the conductive layer, and therefore, warp of chuck top 2 caused by heat treatment can be avoided and chuck top conductive layer 3 can be formed at a low cost.

Particularly, a method of forming a thermally sprayed film on chuck top 2 and then forming a plated film further thereon is preferred. The material thermally sprayed (aluminum, nickel or the like) forms some compound such as oxide, nitride or oxynitride at the time of thermal spraying, and such compound reacts to the surface of chuck top 2, realizing firm contact with the surface. The thermally sprayed film, however, has low electric conductivity because it contains the compound mentioned above. In contrast, plating forms an almost pure metal film, and therefore, a conductive layer of superior electric conductivity can be formed, though contact strength with the surface of chuck top 2 is not as high as that of the thermally sprayed film. The thermally sprayed film and the plated film both contain metal as the main component and, therefore, contact strength therebetween is high. Therefore, by forming a thermally sprayed film as a base and forming a plated film thereon, chuck top conductive layer 3 having both high contact strength and high electric conductivity can be provided.

It is preferred that surface roughness Ra of chuck top conductive layer 3 is at most 0.5 μm. When the surface roughness Ra exceeds 0.5 μm and a device having a high calorific value is inspected, the heat generated from the device itself cannot be radiated from chuck top 2, and the device might possibly be broken by the heat. Surface roughness Ra of at most 0.02 μm is preferred, as more efficient heat radiation becomes possible.

It is preferred that the thickness of chuck top 2 is at least 8 mm. When the thickness is smaller than 8 mm, chuck top 2 much deforms when load is applied at the time of inspection, possibly causing contact failure, and further causing damage to the wafer. It is more preferable that chuck top 2 has the thickness of at least 10 mm, as the possibility of contact failure can further be reduced.

It is preferred that chuck top 2 has Young's modulus of at least 250 GPa. When Young's modulus is smaller than 250 GPa, chuck top 2 much deforms when load is applied at the time of inspection, possibly causing contact failure, and further causing damage to the wafer. Young's modulus of chuck top 2 is preferably at least 250 GPa, and more preferably at least 300 GPa, as the possibility of contact failure can further be reduced.

Chuck top 2 preferably has thermal conductivity of at least 15 W/mK. When the thermal conductivity is lower than 15 W/mK, temperature uniformity of the wafer mounted on chuck top 2 would be deteriorated. When the thermal conductivity is not lower than 15 W/mK, thermal uniformity having no adverse influence on inspection can be attained. Thermal conductivity of 170 W/mK or higher is more preferable, as the thermal uniformity of the wafer can further be improved.

As the material having such Young's modulus and thermal conductivity as described above, various ceramics and metal-ceramics composite materials may be available. Preferred metal-ceramics composite material includes composite material of aluminum and silicon carbide (Al—SiC) and composite material of silicon and silicon carbide (Si—SiC), which have relatively high thermal conductivity and easily realize thermal uniformity when the wafer is heated. Of these, Si—SiC is particularly preferred, as it has high thermal conductivity of 170 W/mK to 220 W/mK and high Young's modulus.

The composite materials described above are conductive and, therefore, as to the method of forming heater body 6, heater body 6 may be formed by forming an insulating layer through a method of thermal spraying or screen printing on a surface opposite to the wafer-mounting surface of chuck top 2, and by forming the conductive layer in a prescribed pattern through a method such as screen printing or vapor deposition.

Alternatively, metal foil of stainless steel, nickel, silver, molybdenum, tungsten, chromium and an alloy of these may be etched to form a prescribed pattern of heater body, to form heater body 6. In this method, insulation from chuck top 2 may be attained by the method similar to that described above, or an insulating sheet may be inserted between chuck top 2 and heater body 6. This is preferable, as the insulating layer can be formed at a considerably lower cost and in a simpler manner than the method described above. The insulating sheet that can be used here includes, from the viewpoint of heat resistance, mica sheet, epoxy resin, polyimide resin, phenol resin and silicone resin. Among these, mica is particularly preferable, as it has superior heat resistance and electric insulation, allows easy processing and is inexpensive.

Use of ceramics as the material for chuck top 2 is advantageous in that formation of an insulating layer between chuck top 2 and heater body 6 is unnecessary. Among ceramics, alumina, aluminum nitride, silicon nitride, mullite, and a composite material of alumina and mullite are preferred as they have relatively high Young's modulus and hence, not much deformed by the load of the probe card. Among these, alumina is preferred as it is relatively inexpensive and has superior insulation at a high temperature. Generally, at the time of sintering, in order to lower sintering temperature, an oxide of alkali-earth metal, silicon or the like is added to alumina. If the amount of addition is reduced and purity of alumina is increased, insulation can further be improved, though the cost increases. With the purity of 99.6%, high insulation can be attained, and with the purity of 99.9%, particularly high insulation can be attained. Further, as the purity increases, alumina comes to have higher insulation and, at the same time, higher thermal conductivity, and with the purity of 99.5%, thermal conductivity of 3 W/mK can be attained. Purity of alumina may appropriately be selected in consideration of insulation, thermal conductivity and cost. Aluminum nitride is preferred as it has particularly high thermal conductivity of 170 W/mK.

As the material of chuck top 2, metal may be applied. In that case, tungsten, molybdenum or an alloy of these having particularly high Young's modulus may be used. Specific alloy may include an alloy of tungsten and copper and an alloy of molybdenum and copper. Such an alloy can be fabricated by impregnating tungsten or molybdenum with copper. Similar to the metal-ceramics composite material described above, these metals are conductors and therefore, the above-described method can directly be applied, to form chuck top conductive layer 3 and further to form heater body 6, and the wafer holder for use is provided.

It is preferred that chuck top 2 deflects at most by 30 μm when a load of 3.1 MPa is applied to chuck top 2. A large number of pins for inspecting the wafer press the wafer from the probe card to chuck top 2, and therefore, the pressure also acts on chuck top 2, and chuck top 2 deflects to no small extent. When the amount of deflection at this time exceeds 30 μm, it becomes impossible to press the pins of the probe card uniformly onto the wafer, and inspection of the wafer might fail. More preferably, the amount of deflection when the load described above is applied is at most 10 μm.

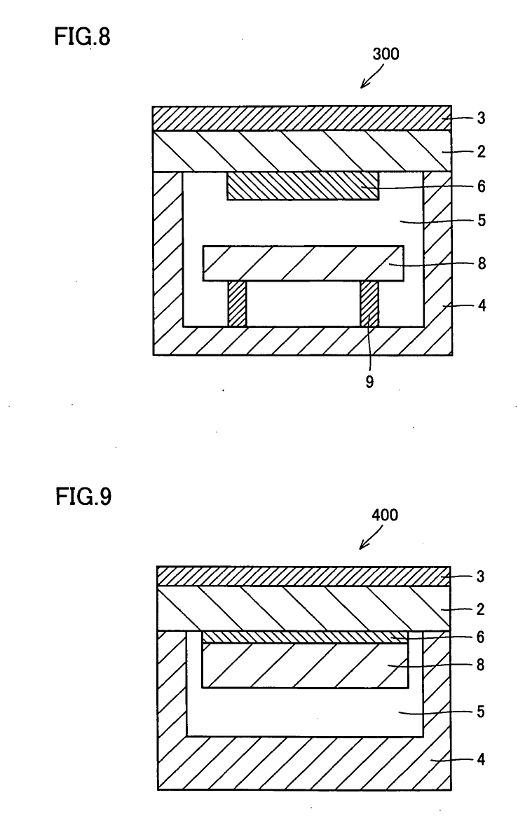

In the present invention, as shown in wafer prober 300 of FIG. 8, a cooling module 8 may be provided in space 5 inside supporter 4. Cooling module 8 is preferred, because when it becomes necessary to cool chuck top 2, chuck top 2 can be cooled rapidly as the heat is removed, and throughput can be improved.

In the present invention, it is preferred that the cooling module is provided on the side opposite to the wafer-mounting surface of the chuck top. In that case, the chuck top can be cooled efficiently in the step of wafer inspection.

As the material of cooling module 8, aluminum, copper and an alloy of these are preferred, because they have high thermal conductivity and capable of removing heat quickly from chuck top 2. It is also possible to use stainless steel, magnesium alloy, nickel or other metal materials. An oxidation-resistant metal film such as nickel, gold, silver or the like may be formed by the method of plating, thermal spraying or the like, to add oxidation resistance to cooling module 8.

Ceramics may also be used as the material for cooling module 8. Among ceramics, aluminum nitride and silicon carbide are preferred as they have high thermal conductivity and are capable of removing heat quickly from chuck top 2. Further, silicon nitride and aluminum oxynitride are preferred, as they have high mechanical strength and superior durability. Oxide ceramics such- as alumina, cordierite and steatite are preferred as they are relatively inexpensive. As described above, the material for cooling module 8 may be selected appropriately in consideration of the intended use, cost and the like. Among these materials, nickel-plated aluminum or nickel-plated copper is particularly preferred, as it has superior oxidation resistance and high thermal conductivity and is relatively inexpensive.

A coolant may be caused to flow in cooling module 8. Causing the coolant flow is preferred, as the heat transferred from chuck top 2 to cooling module 8 can quickly be removed from the cooling module and the cooling rate of chuck top 2 can be improved. Types of the coolant may be selected from liquid such as water, Fluorinert or Galden, or gas such as nitrogen, air or helium. When the temperature of use is always 0° C. or higher, water is preferred considering magnitude of specific heat and cost, and when it is cooled below zero, Galden is preferred considering specific heat.

As the method of forming the passage for the coolant flow, two plates may be prepared, for example, and the passage may be formed by machine processing or the like on one of the plates. In order to improve corrosion resistance and oxidation resistance, entire surfaces of the two plates may be nickel-plated, and thereafter, the two plates may be joined by means of screws or welding. At this time, a sealing member such as an O-ring may be inserted around the passage, to prevent leakage of the coolant.

As another method of forming the flow passage, a pipe through which the coolant flows may be attached to a cooling plate. Here, in order to increase contact area between the cooling plate and the pipe, the cooling plate may be processed to have a trench of an approximately the same cross-sectional shape as the pipe and the pipe may be arranged in the trench, or a flat-shaped portion may be formed on a portion of the cross-sectional shape of the pipe and that flat portion may be fixed on the cooling plate. As to the method of fixing the cooling plate and the pipe, screw fixing using a metal band, welding or brazing may be available. By inserting a deformable substance such as resin between the cooling plate and the pipe, tight contact between the two is attained and cooling efficiency can be enhanced.

At the time of heating chuck top 2, if cooling module 8 can be separated from chuck top 2, efficient temperature elevation of chuck top 2 becomes possible, and therefore, it is preferred that cooling module 8 is movable. As a method of realizing mobile cooling module 8, an elevating mechanism 9 such as an air cylinder may be used. In this case, cooling module 8 does not bear the load of probe card, and therefore, it is free from the problem of deformation caused by the load.

In the present invention, the size of chuck top 2 and heater body 6 has been considered particularly in relation to the heating rate and thermal uniformity when cooling module 8 is provided. As a result, it has been found that, in relation to the thickness and diameter of chuck top 2 and the diameter of the wafer to be inspected, it is preferred to design the maximum outer diameter l and thickness t so that the maximum outer diameter l of the area where heater body 6 exists is made smaller than the diameter L of chuck top 2, and the maximum outer diameter l, thickness t of chuck top 2 and the diameter Wl of the wafer to be inspected satisfy the relation of 1+4t>Wl, to provide cooling module 8 on the side opposite to the wafer-mounting surface of chuck top 2 and to set the diameter of cooling module 8 smaller than the diameter of chuck top 2. In that case, the heating rate and the thermal uniformity can further be improved.

In order to arrange cooling module 8 on the side opposite to the wafer-mounting surface of chuck top 2, it is desired that the diameter of cooling module 8 is made larger than the diameter of heater unit 6. By the present invention, it becomes possible to improve the heating rate and the thermal uniformity, and in connection with cooling module 8, the following contents may also be implemented.

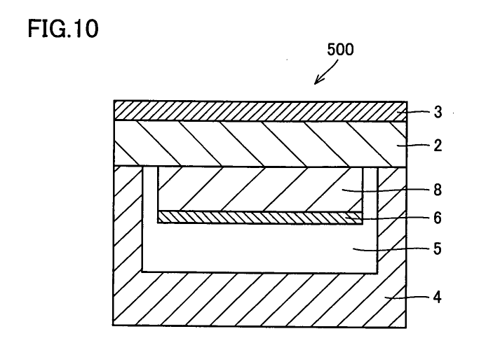

When the cooling rate of chuck top 2 is of high importance, it is preferred to fix cooling module 8 on chuck top 2. As a preferred arrangement, as shown in wafer holder 400 of FIG. 9, heater body 6 may be arranged on the side opposite to the wafer-mounting surface of chuck top 2 and cooling module 8 may be fixed on the lower surface, so that heater body 6 comes to be arranged between chuck top 2 and cooling module 8. As another arrangement, as shown in a wafer holder 500 of FIG. 10, cooling module 8 may be directly provided on a surface opposite to the wafer-mounting surface of chuck top 2, and on a lower surface thereof, heater body 6 may be fixed. Here, it is also possible to insert a deformable and heat-resistant soft material having high thermal conductivity between the surface opposite to the wafer-mounting surface of chuck top 2 and cooling module 8. By providing the soft material between chuck top 2 and cooling module 8 that can moderate warp or parallelism of the two, it becomes possible to enlarge the contact area, and the original cooling performance of the cooling module 8 can more fully be exhibited, realizing higher cooling rate.

In any of the arrangements, the method of fixing chuck top 2, cooling module 8 and heater body 6 is not specifically limited, and by way of example, they may be fixed by a mechanical method such as screw fixing or clamping. When chuck top 2, cooling module 8 and heater body 6 are to be fixed together by screws, three or more screws are preferred as tight contact between each of the members can be improved, and six or more screws are more preferable.

Further, cooling module 8 may be mounted inside the space 5 of supporter 4, or the cooling module may be mounted on the supporter and the chuck top may be mounted thereon. No matter which method is adopted, cooling rate can be increased as compared with the example in which cooling module 8 is movable, as the chuck top and the cooling module are firmly fixed together. When the cooling module is mounted on the supporter, contact area between the cooling module and the chuck top is increased, and it becomes possible to cool the chuck top in a shorter time period.

When cooling module 8 fixed on chuck top 2 can be cooled by a coolant, it is preferred that the flow of coolant to cooling module 8 is stopped when the temperature of chuck top 2 is increased or when it is kept. at a high temperature, because the heat generated by heater body 6 is not removed by the coolant, and whereby efficient temperature increase or maintenance of high temperature becomes possible. Naturally, chuck top 2 can be cooled efficiently by causing the coolant to flow again to cooling module 8 at the time of cooling.

Further, chuck top 2 itself may be formed as the cooling module, by providing a passage through which the coolant flows inside chuck top 2. In that case, the time for cooling can further be reduced than when the cooling module is fixed on the chuck top. As the material for the chuck top, ceramics and metal-ceramics composite material similar to the above may be used. As for the structure, for example, an integrated structure in which the chuck top conductive layer is formed on one surface of a member I to be the wafer-mounting surface, and a passage for the coolant flow is formed on the opposite surface, and a member II is integrated by brazing, glass fixing or screw fixing, on the surface having the passage formed thereon can be provided. Alternatively, a passage may be formed on one surface of member II, and the member may be integrated with member I on the surface having the passage formed thereon, or passages may be made both on members I and II, and the members may be integrated on the surfaces having the passages formed thereon. It is preferred that the difference in thermal conductivity of members I and II is as small as possible, and ideally, the members are preferably formed of the same material.

When the chuck top itself is formed as the cooling module, metal may be used as the material. Metal is advantageous as it is less expensive as compared with the ceramics or composite material of ceramics and metal and it allows easy processing so that formation of the passage is easier. However, it is susceptible to deformation under the load from the probe card, and therefore, a plate-shaped member may be provided for preventing deformation of the chuck top, as the plate for preventing deformation, on the side opposite to the wafer-mounting surface of the chuck top. It is preferred that the plate for preventing deformation has Young's modulus of at least 250 GPa, as in the case where ceramics or metal-ceramics composite material is used as the material for the chuck top.

The plate for preventing deformation may be housed in the space 5 formed in supporter 4, or it may be inserted between the chuck top and supporter 4. The chuck top and the plate for preventing deformation may be fixed by a mechanical method such as screw fixing, or may be fixed by brazing or glass fixing. Efficient heating and cooling is also possible, by not causing coolant to flow through the cooling module when the chuck top is heated or kept at a high temperature and causing the coolant to flow only at the time of cooling, as in the example in which the cooling module is fixed on the chuck top.

When the material of chuck top is metal, the chuck top conductive layer may be newly formed on the wafer-mounting surface, if it is the case that the chuck top material is much susceptible to oxidation or alteration, or it does not have sufficiently high electric conductivity. As the method of forming the chuck top conductive layer, vapor deposition, sputtering, thermal spraying or plating may be used as in the foregoing.

In the structure in which the plate for preventing deformation is provided on the chuck top formed of metal, formation of the electromagnetic shield layer or the guard electrode layer similar to that described above may be possible. By way of example, on the surface opposite to the wafer-mounting surface of the chuck top, an insulated heater body may be provided and covered with a metal layer, and further, the guard electrode layer may be formed with an insulating layer interposed, and between the guard electrode layer and the chuck top, an insulating layer may be formed. Further, the plate for preventing deformation may be arranged, and the chuck top, the heater body and the plate for preventing deformation may be fixed integrally.

The wafer holder in accordance with the present invention may be used as a wafer prober having a structure combined with known components such as a driving apparatus (driving system) for driving the wafer holder in X, Y and Z directions, a wafer conveying apparatus, and a probe card. Further, the wafer holder in accordance with the present invention may also be suitably applied to a handler apparatus or a tester apparatus. The present invention allows inspection without contact failure even of a semiconductor having minute circuitry.

### EXAMPLES

### Example 1

Wafer holder 100 shown in FIG. 1 was fabricated. As chuck top 2, two types of Si-SiC substrates having the diameter of 305 mm and thickness of 10 mm and 15 mm, respectively, were prepared. On one surface of the substrate, a concentric trench and through holes for vacuum chucking a wafer were formed, and nickel plating was applied as the chuck top conductive layer 3, to provide a wafer-mounting surface. Thereafter, the wafer-mounting surface was polished and finished to have the overall warp amount of 10 μm and the surface roughness Ra of 0.02 μm, and chuck top 2 was completed.

Then, mullite-alumina composite body of a pillar shape having the diameter of 305 mm and thickness of 40 mm was prepared as supporter 4, and it was counter-bored to have the inner diameter of 295 mm and the depth of 20 mm. On chuck top 2, stainless steel foil insulated with mica was attached as the electromagnetic shield layer, and further, a resistance heater body sandwiched by mica was attached, to provide heater body 6. Resistance heater bodies were formed by etching three types of stainless steel foils having the diameter of 200 mm, 250 mm and 300 mm, respectively, to a prescribed pattern. Further, a through hole 44 was formed in supporter 4, for connecting an electrode line for feeding power to heater body 62, in the form as shown in FIG. 7. Further, on the side surface and bottom surface of supporter 4, aluminum was thermally sprayed to form a metal layer.

Next, on supporter 4, chuck top 2 with heater body 6 and the electromagnetic shield layer attached was mounted. Thus, wafer holders 100 having six different chuck tops shown in Table 1 were fabricated.

On the wafer-mounting surface of wafer holder 100, a wafer for temperature measurement having the diameter of 300 mm was mounted, and heater body 6 was electrically conducted to heat the wafer from 25° C. to 200° C., the time of heating was measured, and further, temperature distribution at 200° C. was measured. As to the measurement of temperature distribution, using a 17-point type temperature measurement device, temperature was measured at 17 points on the wafer for temperature measurement having the diameter of 300 mm described above, and difference between the highest value and the lowest value of temperature was obtained as temperature distribution. The results are as shown in Table 1.

TABLE 1

| | Chuck top | | Heater body | Wafer | | | Heating | Temp. |
|---|---|---|---|---|---|---|---|---|
| | Diameter | Thickness | diameter | diameter | | | time | distribution |
| No. | (mm) | (mm) | (mm) | (mm) | 1 + 4t | 1 + 4t > Wl | (sec.) | (° C.) |
| 1-1 | 305 | 10 | 300 | 300 | 340 | Satisfied | 2080 | 1.5 |
| 1-2 | 305 | 10 | 250 | 300 | 290 | Unsatisfied | 3120 | 2.8 |
| 1-3 | 305 | 10 | 200 | 300 | 240 | Unsatisfied | 3640 | 4.6 |
| 1-4 | 305 | 15 | 300 | 300 | 360 | Satisfied | 2070 | 1.3 |
| 1-5 | 305 | 15 | 250 | 300 | 310 | Satisfied | 2100 | 1.6 |
| 1-6 | 305 | 15 | 200 | 300 | 260 | Unsatisfied | 3250 | 3.1 |

As can be seen from Table 1, when the diameter of heater body 6 (that is, maximum outer diameter l), chuck top thickness t and wafer thickness we satisfied the relation of 1+4t>Wl, the heating time was short and the temperature distribution was satisfactory.

### Example 2

Wafer holder 300 shown in FIG. 8 was fabricated. As chuck top 2, two types of Si—SiC substrates having the diameter of 305 mm and thickness of 12 mm and 15 mm, respectively, were prepared. On one surface of the substrate, a concentric trench and through holes for vacuum chucking a wafer were formed, and nickel plating was applied as the chuck top conductive layer 3, to provide a wafer-mounting surface. Thereafter, the. wafer-mounting surface was polished and finished to have the overall warp amount of 10 μm and the surface roughness Ra of 0.02 μm, and chuck top 2 was completed.

Then, mullite-alumina composite body of a pillar shape having the diameter of 305 mm and thickness of 40 mm was prepared as supporter 4, and it was counter-bored to have the inner diameter of 295 mm and the depth of 20 mm. On chuck top 2, stainless steel foil insulated with mica was attached as the electromagnetic shield layer, and further, a resistance heater body sandwiched by mica was attached, to provide heater body 6. Resistance heater bodies were formed by etching two types of stainless steel foils having the diameter of 280 mm and 290 mm, respectively, to a prescribed pattern. Further, a through hole 44 was formed in supporter 4, for connecting an electrode line for feeding power to heater body 62, in the form as shown in FIG. 7. Further, on the side surface and bottom surface of supporter 4, aluminum was thermally sprayed to form a metal layer. On chuck top 2 having the thickness of 12 mm, heater body having the diameter of 290 mm was attached, and on chuck top 2 having the thickness of 15 mm, heater body 6 having the diameter of 280 mm was attached, respectively.

Copper plates having the thickness of 5 mm and diameter of 275 mm, 285 mm, 295 mm and 310 mm, respectively, were prepared. On one copper plate, a flow passage was formed, and another copper plate was welded, whereby cooling modules having the flow passage for passing coolant therein were fabricated.

Next, on supporter 4, chuck top 2 with heater body 6 and the electromagnetic shield layer attached was mounted, and cooling module 8 was attached. Thus, wafer holders having four different types of chuck tops shown in Table 2 were fabricated.

On the wafer-mounting surface of wafer holder 200, a wafer for temperature measurement having the diameter of 300 mm was mounted, and heater body 6 was electrically conducted to heat the wafer from 25° C. to 200° C., the time of heating was measured, and further, temperature distribution at 200° C. was measured. As to the measurement of temperature distribution, using a 17-point type temperature measurement device, temperature was measured at 17 points on the wafer for temperature measurement having the diameter of 300 mm described above, and difference between the highest value and the lowest value of temperature was obtained as temperature distribution. The relation in the size among chuck top 2, heater body 6 and the wafer, and the result of measurement of heating rate and temperature distribution at 200° C. are as shown in FIG. 3.

TABLE 2

| | Chuck top | | | | |
|---|---|---|---|---|---|
| | | Thick- | Heater body | Wafer | Cooling module |
| | Diameter | ness | diameter | diameter | diameter |
| No. | (mm) | (mm) | (mm) | (mm) | (mm) |
| 2-1 | 305 | 12 | 290 | 300 | 295 |
| 2-2 | 305 | 12 | 290 | 300 | 285 |
| 2-3 | 305 | 15 | 280 | 300 | 285 |
| 2-4 | 305 | 15 | 280 | 300 | 275 |

TABLE 3

| | Relation between component sizes | | | | | |
|---|---|---|---|---|---|---|
| | | | Cooling | Cooling | | Temp. |
| | | | module | module | Heating time | distribution |
| No. | 1 + 4t | 1 + 4t > Wl | diameter < L | diameter > l | (sec) | (° C.) |
| 2-1 | 338 | Satisfied | Satisfied | Satisfied | 2097 | 1.0 |
| 2-2 | 338 | Satisfied | Satisfied | Unsatisfied | 2108 | 1.5 |
| 2-3 | 340 | Satisfied | Satisfied | Satisfied | 2085 | 1.1 |
| 2-4 | 340 | Satisfied | Satisfied | Unsatisfied | 2104 | 1.3 |

As can be seen from Table 3, when the diameter of the cooling module was larger than the diameter of the heater body (that is, the maximum outer diameter l), the heating time was shorter and the temperature distribution was better.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A wafer holder, comprising a chuck top, a chuck top conductive layer formed on a surface of said chuck top, and a heater body formed on a portion other than the portion where said chuck top conductive layer is formed, of said chuck top; wherein
maximum outer diameter l of an area where said heater body exists is smaller than diameter L of said chuck top; and
the maximum outer diameter l of the area where said heater body exists, and thickness t of said chuck top are set such that the maximum outer diameter l, the thickness t and diameter Wl of a wafer to be inspected satisfy the relation of 1+4t>Wl.

2. The wafer holder according to claim 1, further having a cooling module on a side opposite to a wafer-mounting surface of said chuck top, wherein diameter of said cooling module is smaller than the diameter of said chuck top.

3. The wafer holder according to claim 2, wherein the diameter of said cooling module is larger than that of said heating body.

4. The wafer holder according to claim 2, wherein said cooling module is fixed on the chuck top.

5. The wafer holder according to claim 2, wherein said heater body is arranged between said chuck top and said cooling module.

6. The wafer holder according to claim 1, wherein said heating body is arranged on a surface opposite to a wafer-mounting surface of said chuck top.

7. A wafer prober comprising the wafer holder according to claim 1.
